(19) United States
(12) Patent Application Publication
(10) Pub. No.: US 2015/0064876 A1
(43) Pub. Date: Mar. 5, 2015

(54) SEPARATING DEVICE AND SEPARATING METHOD

(71) Applicant: KABUSHIKI KAISHA TOSHIBA, Tokyo (JP)

(72) Inventor: Kazuhiro IIZUKA, Kanagawa (JP)

(73) Assignee: KABUSHIKI KAISHA TOSHIBA, Tokyo (JP)

(21) Appl. No.: 14/194,612

(22) Filed: Feb. 28, 2014

(30) Foreign Application Priority Data
Aug. 30, 2013 (JP) 2013-180230

(51) Int. Cl. H05K 13/00; H01L 21/50

(52) U.S. Cl. CPC H05K 13/00; H01L 21/50; H01L 2021/607
USPC 438/460; 29/762

(57) ABSTRACT

A separating device separates a chip mounted on a substrate through a connecting material, from the substrate. The separating device includes a heating unit that heats the substrate at a temperature less than a melting point of the connecting material.

### CROSS-REFERENCE TO RELATED APPLICATION

This application is based upon and claims the benefit of priority from Japanese Patent Application No. 2013-180230, filed Aug. 30, 2013, the entire contents of which are incorporated herein by reference.

### FIELD

Embodiments described herein relate generally to a separating device and a separating method.

### BACKGROUND

In general, electronic circuits mounted on a substrate are joined to the substrate using, for example, one or more solder balls.

### BRIEF DESCRIPTION OF THE DRAWINGS

FIG. 1 is a cross sectional view illustrating an apparatus for separating an electronic device from a mounting substrate, according to a first embodiment.

FIGS. 2A and 2B are cross sectional views illustrating ways a chip may be separated from a mounting substrate according to the first embodiment.

FIG. 3 is a flow chart illustrating a method of separating a chip from a mounting substrate according to the first embodiment.

FIG. 4 is a cross sectional view illustrating a separating device according to a first variation of the first embodiment.

FIG. 5 is a cross sectional view illustrating a separating device according to a second variation of the first embodiment.

FIG. 6 is a cross sectional view illustrating a separating device according to a third variation of the first embodiment.

FIG. 7 is a cross sectional view illustrating a separating device according to a second embodiment.

FIGS. 8A and 8B are cross sectional views illustrating ways of separating a chip from a mounting substrate according to the second embodiment.

FIG. 9 is a flow chart illustrating a method of separating a chip from a mounting substrate according to the second embodiment.

FIG. 10 is a cross sectional view illustrating a device for separating a chip from a mounting substrate according to a variation of the second embodiment.

### DETAILED DESCRIPTION

In general, according to one embodiment, a device for separating a chip from a mounting substrate and a separating method for a chip that prevents excessive damage to the chip is provided.

According to one embodiment, a separating device that removes a chip connected to a mounting substrate through a connecting material from the mounting substrate is provided. The separating device includes a heating unit that heats the mounting substrate to a temperature less than a melting point of the connecting material.

According to one embodiment, a separating method for removing a chip connected to a mounting substrate through a connecting material from the mounting substrate is provided. The separating method includes heating the mounting substrate to a temperature less than a melting point of the connecting material.

Hereinafter, embodiments are described with reference to the drawings.

A first embodiment is described herein.

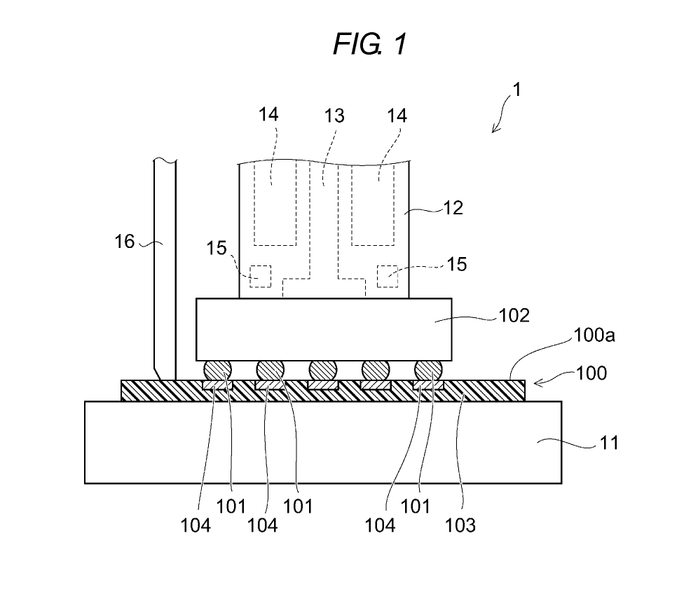

As illustrated in FIG. 1, a separating device 1 according to the embodiment is a device for removing a chip 102 connected to a mounting substrate 100 through a connecting material such as solder balls 101 from the mounting substrate 100. In the mounting substrate 100, there is wiring (not illustrated) made of metal such as copper and an electrode pad 104 within a base material 103 made of resin material. The electrode pad 104 is exposed to the mounting surface 100a of the mounting substrate 100.

The separating device 1 includes a heating unit 11 for holding and heating the mounting substrate 100. The heating unit 11 is a heater of, for example, resistant heating type, which heats the mounting substrate 100 to a temperature less than the melting point of the solder ball 101 and preferably, to a temperature less than the glass transition point of the resin material forming the base material 103 of the mounting substrate 100. The melting point of the solder ball 101 is, for example, 220 to 240° C., although this depends on the composition thereof. The glass transition point of the resin material is, for example, about 180° C. although this depends on the type of resin material.

Further, the separating device 1 includes a holding unit 12 for holding the chip 102. Within the holding unit 12, there is an absorption tool 13 for holding the chip 102. Further, within the holding unit 12, there is a cooling unit 14 for cooling the chip 102. The cooling unit 14 is, for example, a tank that contains liquid nitrogen. Further, within the holding unit 12, there is h an ultrasonic wave applying unit 15 for applying an ultrasonic wave to the solder balls 101. Further, the separating device 1 is provided with a shearing tool 16 which presses the chip 102 in a direction parallel to the mounting surface 100a of the mounting substrate 100.

Next, the operation of the separating device, and a method of separating a chip from a mounting substrate according to the first embodiment, is described.

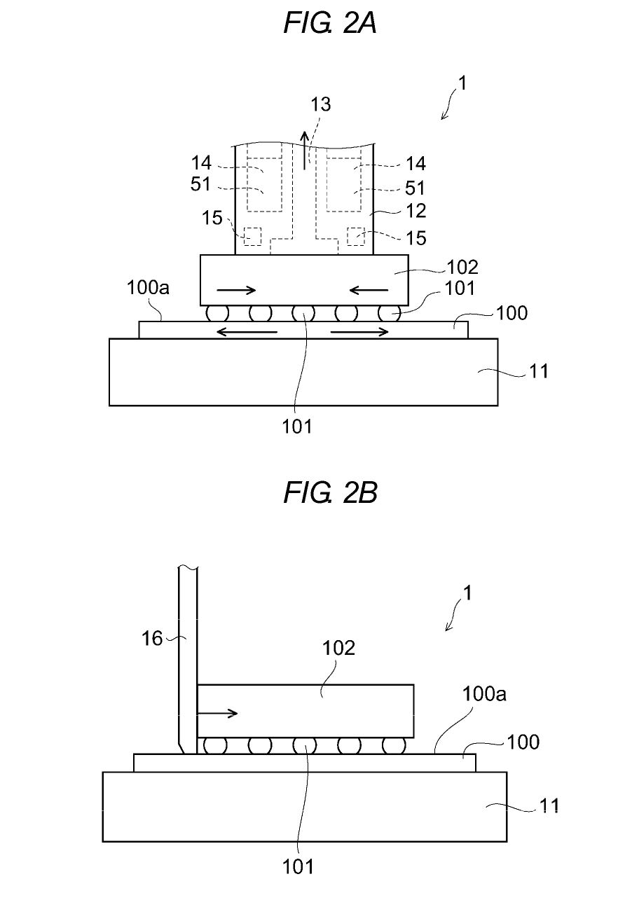

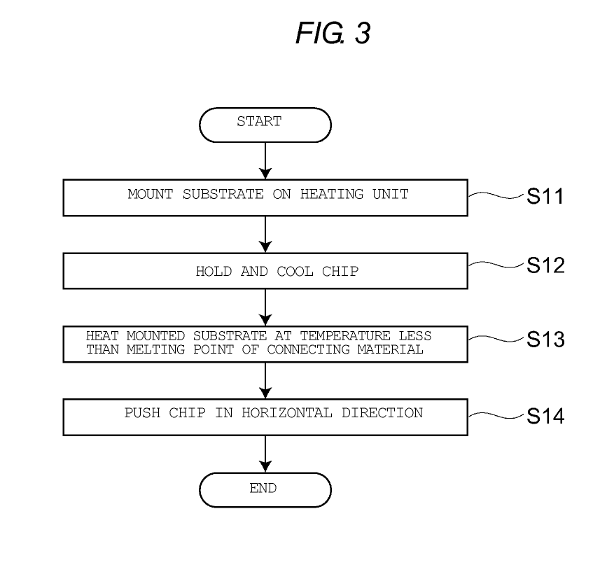

As illustrated in FIG. 2A and in Step S11 of FIG. 3, the mounting substrate 100 is mounted on the heating unit 11. In FIG. 3, the shearing tool 16 (referring to FIG. 1) is not depicted with the mounting substrate 100. The solder ball 101 is joined to the electrode pad 104 of the mounting substrate 100. Electrode pads (not illustrated in FIG. 3) of the chip 102 are joined to the solder ball 101. According to this embodiment, the chip 102 is mounted on the mounting substrate 100 through the solder balls 101.

The chip 102 may be, for example, a chip of a Ball Grid Array (BGA) type and, for example, a NAND flash memory or a large scale integrated circuit (LSI) built on the silicon substrate. The solder balls 101 are joined to the lower surface of the chip 102 in a matrix configuration and are, respectively, joined to the electrode pads 104 of the mounting substrate 100.

Next, as illustrated in Step S12 of FIG. 3, by applying vacuum through the absorption tool 13 of the holding unit 12, the holding unit 12 holds the chip 102. Further, by supplying liquid nitrogen 51 into the cooling unit 14, the holding unit 12 cools the chip 102. In this state, as illustrated in Step S13 of FIG. 3, the heating unit 11 heats the mounting substrate 100. The temperature of the mounting substrate that results from the heating is a temperature that is less than that of the melting point of the solder ball 101; preferably, the temperature is less than the glass transition point of the resin material forming the base material 103 of the mounting substrate 100 (e.g., a temperature of, less than 180° C.). In this embodiment, the ultrasonic wave applying unit 15 of the holding unit 12 supplies an ultrasonic wave. This ultrasonic wave is applied to the solder balls 101 through the chip 102.

According to this embodiment, the mounting substrate 100 is heated by the heating unit 11 and is thermally expanded. Therefore, a force going from the central portion to the peripheral portion of the chip 102 is applied to each solder ball 101 from the mounting substrate 100. On the other hand, as it is cooled by the cooling unit 14, the chip 102 is thermally contracted, or it is at least restrained from thermally expanding. Therefore, the respective solder balls 101 are restrained from moving by the chip 102 and a force going from the peripheral portion to the central portion of the chip 102 is applied to the solder balls 101.

According to this embodiment, mutually adverse forces from the mounting substrate 100 and the chip 102 are applied to the solder balls 101, thereby generating a shearing force. This shearing force is larger for solder balls 101 joined in the more peripheral portion of the chip 102. Further, due to the ultrasonic wave applied by the ultrasonic wave applying unit 15, the solder balls 101 fatigue and are easily fractured. As the result, at least the solder balls 101 joined in the peripheral portion of the chip 102 fracture. On the other hand, in some cases, the solder balls 101 joined in the central portion of the chip 102 do not fracture.

Next, as illustrated in FIG. 2B, where the holding unit 12 is not depicted, the shearing tool 16 is arranged on the lateral side of the chip 102. As illustrated in Step S14 of FIG. 3, the shearing tool 16 pushes against the chip 102 in a horizontal direction, that is, in a direction parallel to the mounting surface 100a of the mounting substrate 100. According to this embodiment, an equal shearing force is applied to all the solder balls 101 that do not fracture. As a result, in the process shown in FIG. 2A, even when the solder balls 101 joined in the central portion of the chip 102 do not fracture, all the solder balls 101 fracture in the process shown in FIG. 2B. According to this embodiment, the chip 102 can be removed from the mounting substrate 100.

Hereafter, potential effects of the embodiment are described.

After the chip 102 is mounted on the mounting substrate 100, when some defect happens in the chip 102, the chip 102 is removed from the mounting substrate 100 by heating the solder balls 101 and is examined. However, if the solder balls 101 are heated to a temperature greater than or equal to their melting point, the chip 102, which is also heated with the solder balls 101, is damaged by heating. If the chip 102 is damaged by heating, a defect that results from the heat damage may not be targeted for examination. Further, the heat damage may cause another defect that originally would not have occurred in the chip 102.

Therefore, in the embodiment, the heating unit 11 heats and thermally expands the mounting substrate 100, and the cooling unit 14 cools and contracts the chip 102, or at least does not thermally expand the chip to a large extent. According to this embodiment, a shearing force is applied to the solder balls 101, which can fracture the solder balls 101. Thus, in the embodiment, the chip 102 is not heated to the melting point of the solder ball 101, but instead to a lower temperature than the melting point of the solder balls. Thus, the solder balls 101 are fractured by the application of a mechanical force. Therefore, the chip 102 is rarely damaged by heating. Further, the chip 102 is cooled by the cooling unit 14 and can be prevented from being damaged by heat. As a result, the chip 102 having a defect generated can be removed from the mounting substrate 100 for examination of the defect, thereby enabling accurate examination.

Further, in the embodiment, since the heating temperature by the heating unit 11 is set at a temperature less than the glass transition point of the resin material forming the base material 103, the mounting substrate 100 can be restrained from being thermally damaged. However, when the mounting substrate 100 is not reused after removing the chip 102, the heating temperature by the heating unit 11 is not restricted to a temperature less than the glass transition point of the resin material, but may be raised to an upper limit in the range where the chip 102 is free from heat damage.

Further, in the embodiment, after heat stress is applied to the solder balls 101 in the process shown in FIG. 2A, a shearing force is applied to the solder balls 101 by the shearing tool 16 in the process shown in FIG. 2B. According to this embodiment, even when the solder balls 101 joined to the central portion of the chip 102 are not fractured by the heat stress, these solder balls 101 may be fractured.

Further, when the solder balls 101 are sheared by the shearing tool 16, at least the solder balls 101 joined in the peripheral portion of the chip 102 have already been fractured and, therefore, a shearing force can be concentrated on the remaining solder balls 101. Further, since a solder ball 101 which is not fractured is nonetheless damaged by heat stress, this damage serves as a starting point of fracture. According to this embodiment, the remaining solder balls 101 can be reliably fractured, hence enabling removal of the chip 102 from the mounting substrate 100.

Further, in the embodiment, the ultrasonic wave applying unit 15 applies an ultrasonic wave to the solder balls 101. This also accelerates the fracture of the solder balls 101.

In the embodiment, although the example depicted provides a cooling unit 14 within the holding unit 12, the cooling unit 14 does not need to be provided. When the chip 102 is positively heated, a heat stress can be generated in the solder balls 101. Further, if the holding unit 12 is formed of a material of high heat conductivity (for example, copper), the chip 102 can be cooled through discharging heat through the holding unit 12.

Further, when the heat stress can fracture most of the solder balls 101, the shearing tool 16 does not necessarily need to be provided. In this case, by pulling the chip 102 using the holding unit 12, the chip 102 can be removed from the mounting substrate 100.

Next, a first variation of the first embodiment is described.

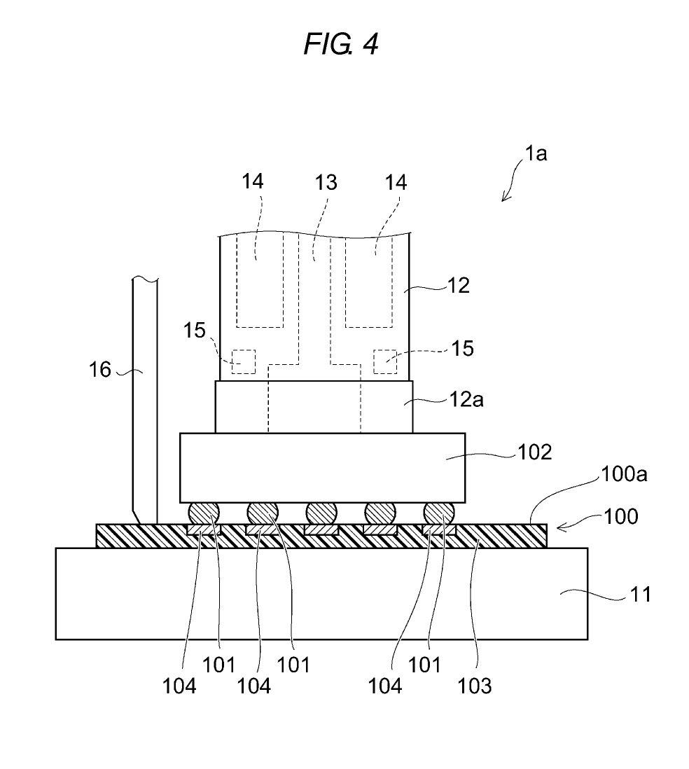

As illustrated in FIG. 4, in a separating device 1a according to the first variation, the lower portion 12a of the holding unit 12 is exchangeable. A plurality of lower portions 12a of various sizes are prepared and exchanged according to the size of the chip 102. According to this first variation, optimal holding units 12 that are suitable for chips 102 of varying sizes can be realized. The structure, operation, and effects, other than those disclosed above, are the same as those in the first embodiment.

Next, a second variation of the first embodiment is described.

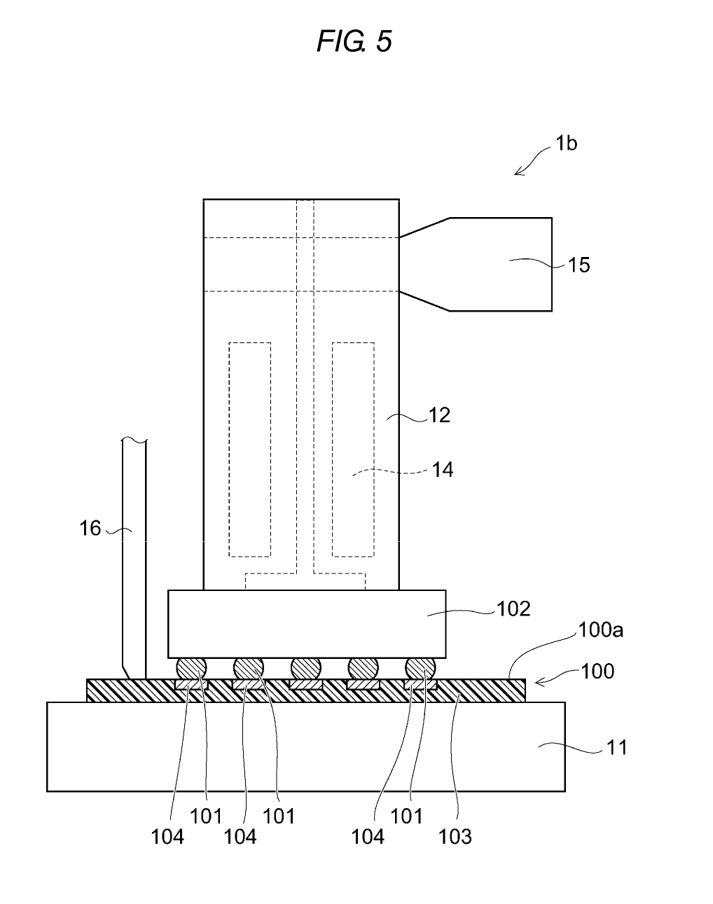

As illustrated in FIG. 5, in a separating device 1b according to the second variation, the cooling unit 14 is positioned lower than the ultrasonic wave applying unit 15, which is shown as positioned on the side of the holding unit 12. According to this variation, the chip 102 can be more efficiently cooled. The structure, operation, and potential effects, other than those disclosed above, are the same as those in the first embodiment.

Next, a third variation of the first embodiment is described.

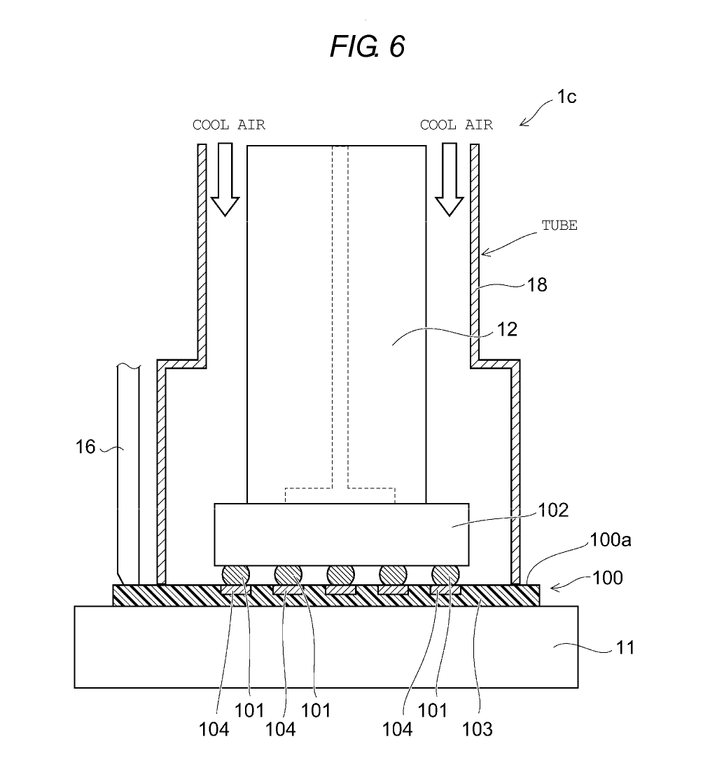

As illustrated in FIG. 6, the separating device 1c according to the first embodiment is provided with a cylindrical tube 18 covering the solder balls 101, the chip 102, and the holding unit 12. Further, the separating device 1c is not provided with a cooling unit within the holding unit 12.

In this example, by blowing a cool air downward from the top of the device, the chip 102 is cooled by the tube 18. According to this, the same effect as that of the first embodiment can be obtained. The structure, operation, and effect, other than those disclosed above, are the same as those of the first embodiment.

Next, a second embodiment is described.

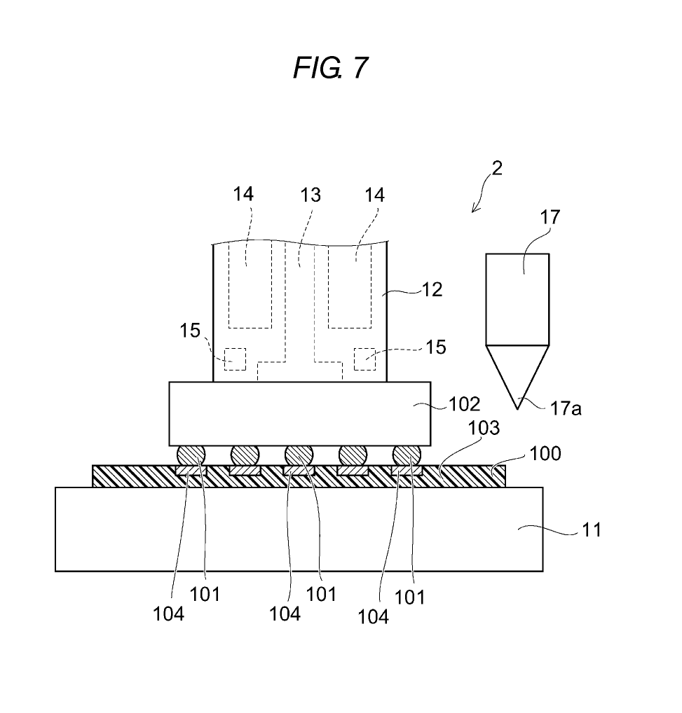

As illustrated in FIG. 7, a separating device 2 according to the second embodiment is different from the above-mentioned separating device 1 (referring to FIG. 1) of the first embodiment in that the shearing tool 16 is not provided and that a dispenser 17 is provided. The dispenser 17 is an injecting means that holds a thermosetting material 52 that is in a liquid or semi-cured state, and which discharges the thermosetting material 52 from a nozzle 17a at the lower end. The thermosetting material 52 is a thermally expandable material capable of expanding by the application of heat, light, such as ultraviolet light or infrared light, or vibration from an electromagnetic wave or ultrasonic wave. In the second embodiment, for example, a material that expands upon heating is used. The structure, other than the above-mentioned components of the separating device 2, is the same as that in the above-mentioned separating device 1.

Next, the operation of the separating device thus constituted, namely, a method of separating a chip from a mounting substrate according to the second embodiment, is described.

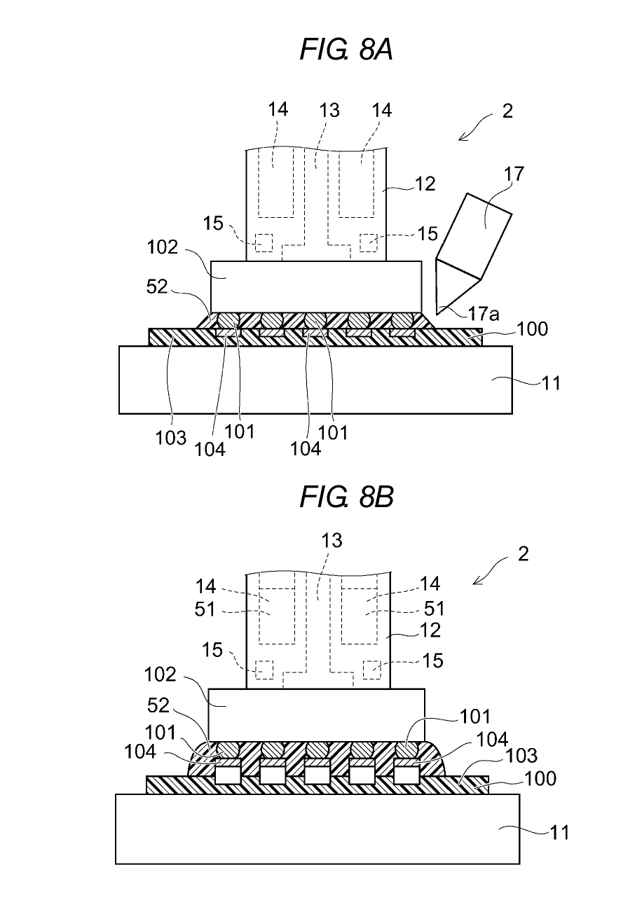

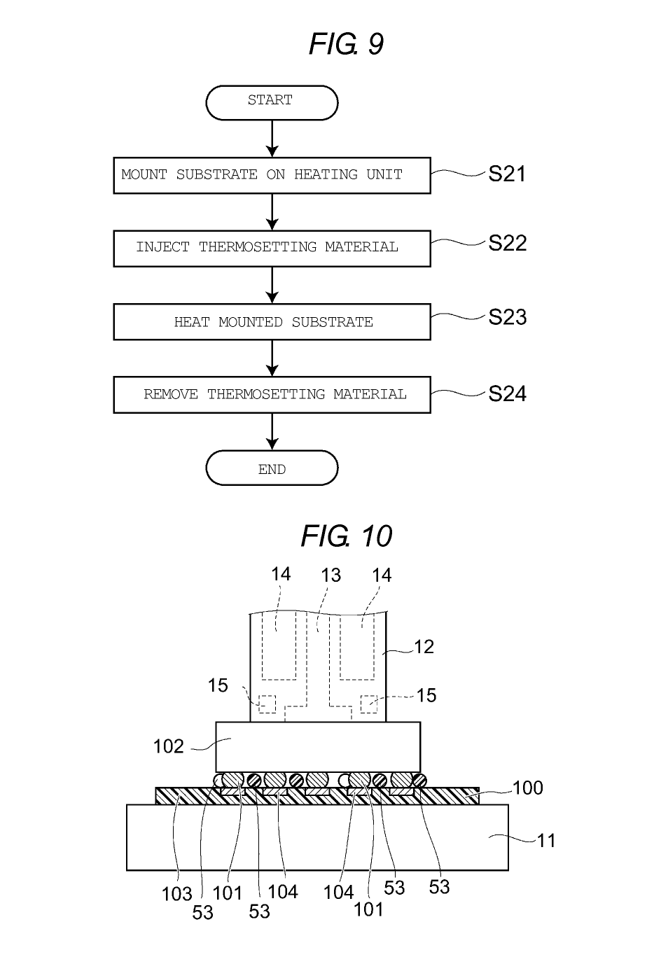

As illustrated in FIG. 8A and in Step S21 of FIG. 9, the mounting substrate 100 is mounted on the heating unit 11. The chip 102 is mounted on the mounting substrate 100 through the solder balls 101. As illustrated in Step S22 of FIG. 9, while inclining the dispenser 17 and discharging the thermosetting material 52 from the nozzle 17a of the dispenser 17, the thermosetting material 52 is injected between the mounting substrate 100 and the chip 102. The thermosetting material 52 may be a resin material which is cured and expanded by heating. For example, polyimide resist can be used.

Next, as illustrated in FIG. 8B and in Step S23 of FIG. 9, while the absorption tool 13 of the holding unit 12 is holding the chip 102, the heating unit 11 heats the mounting substrate 100. According to this, the thermosetting material 52 is heated through the mounting substrate 100. As a result, the thermosetting material 52 is cured and thermally expanded. According to this embodiment, the chip 102 is raised upward to separate from the mounting substrate 100. In this embodiment, the location of a fracture depends on the portion of the chip 102 that is joined to the mounting substrate. For example, the electrode pad 104 of the mounting substrate 100 may be separated from the base material 103. The heating temperature at this point has to be a temperature at which the thermosetting material 52 may be cured and thermally expanded, while being less than the melting point of the solder ball 101. In addition, the heating temperature is less than the glass transition point of the resin material forming the base material 103.

In this embodiment, the chip 102 may be cooled by the cooling unit 14. This can protect the chip 102 from heat damage and a fracture can be accelerated by the generation of a shearing force due to heat stress. Alternatively, an ultrasonic wave may be generated by the ultrasonic wave applying unit 15. This can also accelerate a fracture.

Thereafter, as illustrated in Step S24 of FIG. 9, the thermosetting material 52 is removed. For example, by irradiating a laser light to the thermosetting material 52, the thermosetting material 52 is decomposed. Alternatively, using chemicals, the thermosetting material 52 is dissolved. According to this embodiment, the chip 102 can be removed from the mounting substrate 100.

Next, potential effects of the embodiment are described.

According to the second embodiment, after the dispenser 17 injects the thermosetting material 52 between the chip 102 and the mounting substrate 100, the thermosetting material 52 is heated so as to be cured and expanded, and hence to apply a separating force to the chip 102 and the mounting substrate 100. According to this embodiment, the chip 102 is not heated to such a temperature as to melt the solder balls 101, but a mechanical force is generated between the chip 102 and the mounting substrate 100 to remove the chip 102 from the mounting substrate 100. According to this embodiment, the chip 102 can be removed from the mounting substrate 100 while being restrained from heat damage.

The structure, operation, and effects, other than those mentioned above with respect to the second embodiment, are the same as those in the above mentioned first embodiment.

Next, a variation of the second embodiment is described.

As illustrated in FIG. 10, in the variation, a bead 53 is used as a thermal expanding material. The bead 53 is a sphere, for example, made of a hard resin material.

At first, the beads 53 are interposed between the mounting substrate 100 and the chip 102. Next, by heating the beads 53, the beads 53 are thermally expanded, to apply a separating force to the chip 102 and the mounting substrate 100. According to this, the chip 102 can be removed from the mounting substrate 100.

Also in this variation, by generating a mechanical force through a thermal expansion, the chip 102 can be removed from the mounting substrate 10, while being restrained from heat damage. Further, according to the variation, after the chip 102 is removed from the mounting substrate 100, the beads 53 that are the expanding material are easily removed.

The structure, operation, and effects, other than those mentioned with respect to the above-mentioned variation, are the same as those in the above-mentioned second embodiment.

In addition, the type of the bead 53 is not restricted to any one particular type. However, the size of the bead 53 before expansion should be small enough to allow the bead to be interposed between the mounting substrate 100 and the chip 102, the size of the bead 53 after expansion should be large enough to allow the bead to make contact with both the mounting substrate 100 and the chip 102, and the hardness of the bead after the expansion should be high enough to fracture a part of the joining structure, including the solder balls 101 the electrode pad 104, and the base material 103 of the mounting substrate 100.

Although the second embodiment and the variation thereof show the use of an expanding material that is thermally expansible by heating, the disclosed embodiments are not restricted to such materials. For example, a material that expands through irradiation or application of a magnetic field may be used. Alternatively, a material that expands by using a chemical method may be used. According to these variations, heat damage to the chip 102 is more likely to be avoided.

According to the embodiments as mentioned above, a separating device and a separating method of a chip capable of restraining a damage of the chip is provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for separating a chip from a substrate on which the chip is mounted through connective members, the method comprising:
heating the substrate to a temperature that is less than a melting point of the connective members while cooling the chip; and
after said heating, separating the chip from the substrate.

2. The method of claim 1, wherein the chip is held with a holding unit that includes a cooling unit that carries out the cooling of the chip.

3. The method of claim 1, wherein the chip is cooled by covering the chip with a tube and blowing cool air into the tube.

4. The method of claim 1, wherein the chip is separated from the substrate by applying a force to the chip in a direction parallel to a surface of the substrate to which the chip is mounted.

5. The method of claim 1, further comprising:
applying an ultrasonic wave to the connective members.

6. The method of claim 5, wherein the chip is held with a holding unit that includes an ultrasonic generator that generates the ultrasonic wave and a cooling unit that carries out the cooling of the chip.

7. A method for separating a chip from a substrate on which the chip is mounted through connective members, the method comprising:
injecting a thermosetting material between the substrate and the chip;
heating the substrate to a temperature less than a melting point of the connective members; and
after said heating, removing the thermosetting material.

8. The method of claim 7, wherein a curing temperature of the thermosetting material is less than the melting point of the connective members.

9. The method of claim 7, further comprising:
applying an ultrasonic wave to the connective members.

10. The method of claim 7, further comprising:
cooling the chip while heating the substrate.

11. An apparatus for separating a chip from a substrate on which the chip is mounted through connective members, the apparatus comprising:
a heating unit configured to heat the substrate to a temperature that is less than a melting point of the connective members; and
a separating member configured to apply a force to the chip to separate the chip from the substrate.

12. The apparatus of claim 11, wherein the heat unit is configured to heat the substrate from a side of the substrate opposite to the chip side.

13. The apparatus of claim 11, further comprising:
a cooling unit configured to cool the chip while the substrate is being heated.

14. The apparatus of claim 13, wherein the cooling unit is configured to cool the chip from a side of the chip opposite to the substrate side.

15. The apparatus of claim 14, further comprising:
an ultrasonic generator disposed closer to the connective members than the cooling unit and configured to generate and apply ultrasonic waves to the connective members.

16. The apparatus of claim 14, further comprising:
an ultrasonic generator disposed farther from the connective members than the cooling unit and configured to generate and apply ultrasonic waves to the connective members.

17. The apparatus of claim 13, wherein the cooling unit includes a tube enclosing the chip and into which cooling air is supplied when the substrate is heated.

18. The apparatus of claim 11, wherein the separating member is configured to apply a lateral force to the chip.

19. The apparatus of claim 11, wherein the separating member includes a thermosetting resin applied between the chip and the substrate that expands upon heating of the substrate to separate the chip from the substrate

20. The method of claim 19, wherein the chip is mounted to the substrate through a plurality of connective members and a curing temperature of the thermosetting material is less than a melting point of the connective members.
